(19) United States
(12) Patent Application Publication
(10) Pub. No.: US 2020/0218160 A1
(43) Pub. Date: Jul. 9, 2020

(54) METHOD FOR CHARACTERISING AT LEAST ONE OPTICAL COMPONENT OF A PROJECTION EXPOSURE APPARATUS

(71) Applicant: Carl Zeiss SMT GmbH, Oberkochen (DE)

(72) Inventors: Wilbert KRUITHOF, Aalen (DE); Dirk Heinrich EHM, Beckingen (DE); Dmitry KLOCHKOV, Schwaebisch Gmuend (DE); Thomas KORB, Schwaebisch Gmuend (DE)

(21) Appl. No.: 16/825,740

(22) Filed: Mar. 20, 2020

Related U.S. Application Data
(63) Continuation of application No. PCT/EP2018/075195, filed on Sep. 18, 2018.

(30) Foreign Application Priority Data
Sep. 21, 2017 (DE) 10 2017 216 703.3

(51) Int. Cl. G03F 7/20

(52) U.S. Cl. CPC G03F 7/702; G03F 7/7085; G03F 7/70133; G03F 7/70508; G03F 7/70166; G03F 7/70075; G03F 7/701

(57) ABSTRACT

In a method for characterizing at least one optical component of a projection exposure apparatus (1), an intensity distribution of the illumination radiation (2) is detected in a field plane of the projection exposure apparatus (1) with a measuring device (31) and predicted values of an optical parameter are spatially determined therefrom over at least one predefined surface.

### CROSS REFERENCE TO RELATED APPLICATIONS

This is a Continuation of International Application PCT/EP2018/075195 which has an international filing date of Sep. 18, 2018, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2017 216 703.3 filed on Sep. 21, 2017.

### FIELD OF INVENTION

The invention relates to a method for characterizing at least one optical component of a projection exposure apparatus. The invention furthermore relates to a system for characterizing at least one optical component of a projection exposure apparatus, and to a projection exposure apparatus comprising such a system.

### BACKGROUND

The basic construction of a microlithographic projection exposure apparatus is known from the prior art. As a representative example, reference should be made to the description of DE 10 2010 062 763 A1, for example. Such apparatuses can comprise in particular an illumination system having a radiation source for generating illumination radiation and an illumination optical unit for transferring the illumination radiation from the radiation source to an object field. They can additionally comprise a projection optical unit for imaging a reticle arranged in the object field onto a wafer arranged in an image field. Both the illumination optical unit and the projection optical unit and optionally the radiation source module usually comprise a multiplicity of optical components that are subject to change processes, in particular the usual aging processes. It is therefore desirable to monitor these optical components, in particular the optical properties thereof. DE 10 2006 039 895 A1 discloses a method for correcting imaging variations produced by intensity distributions in optical systems. WO 2012/076335 A1 discloses a method for measuring an optical system.

### SUMMARY

It is an object of the invention to improve over known methods for characterizing at least one optical component of a projection exposure apparatus.

According to one formulation of the invention an intensity distribution of the illumination radiation is detected in a field plane of the projection exposure apparatus, and predicted values of an optical parameter over at least one predefined surface are determined from the measurement data. With the aid of the predicted values determined, a deviation thereof from predefined reference values can then be determined.

In accordance with one aspect of the invention, the measuring device is impinged on with illumination radiation a number of times. It is impinged on with illumination radiation a number of times in particular sequentially, that is to say with temporal spacing. In this case, it can be impinged on with illumination radiation a number of times using the same selection of illumination channels. As an alternative thereto, the selection of the illumination channels used for impinging on the measuring device with illumination radiation can also be altered between different measurements. Combinations are likewise possible. The impingement on the measuring device with illumination radiation is effected here by impingement on the object field with illumination radiation.

A repeated measurement of the intensity distribution of the illumination radiation can be used in particular for monitoring the optical quality of the components of the projection exposure apparatus, in particular for detecting degradation effects.

The method makes possible a statement about whether a specific, predefined optical component of the projection exposure apparatus lies within a tolerance range of predefined specifications. On the basis of the determined deviation of the predicted values of the optical parameter from the reference values, it is possible to assess whether this deviation can be compensated for or whether a specific optical component must be exchanged. On the basis of the determined deviation of the predicted values from the reference values, in particular an adaptation, in particular an optimum adaptation, of the system to the given conditions can be effected.

The downtime that arises for service work on the projection exposure apparatus can be reduced with the aid of the method according to the invention.

The optical parameter whose values are predicted from the detected intensity distribution can be the intensity distribution of the illumination radiation or the profile of the reflectivity/transmissivity over the surface of an optical component.

Provision is made, in particular, for determining not only absolute values of the optical parameter, but rather the deviation thereof from reference values. The latter can be, in particular, results of a previous measurement. In accordance with one aspect of the invention, the method serves in particular for determining and/or monitoring the change in the optical parameter and/or in the predicted values thereof.

The optical parameter which is determined from the detected intensity distribution is, in particular, the reflectivity of a mirror. Said parameter can also be the transmissivity of a lens element, of a filter, of a stop, of a protective film, for example of a pellicle or of a DGL membrane (dynamic gas lock; see WO 2014/020003 A1), or of a manipulator. A manipulator should be understood here generally to mean an optical component which can be used to influence the intensity distribution in the beam path of the illumination radiation. In particular, the spatial dependence of the reflectivity or transmissivity of an optical component, in particular over the surface thereof, can be determined from the detected intensity data.

The method according to the invention serves, in particular, for monitoring at least one of the optical components of a projection exposure apparatus over time. It makes it possible, in particular, to detect a deterioration (degradation) of at least one optical component of a projection exposure apparatus.

It makes it possible, in particular, to characterize a plurality of optical components of the projection exposure apparatus, in particular all beam guiding elements of the illumination optical unit and/or the projection optical unit or a predefined selection thereof.

If only the constituent parts of the illumination system are intended to be monitored, it is not absolutely necessary to provide a projection optical unit.

However, the method can advantageously be carried out on an entire projection exposure apparatus. It can be carried out in particular in situ, in particular online. Switching off the apparatus, in particular removing the optical component or components to be characterized, is not necessary. The monitoring of the optical quality of the components of the projection exposure apparatus over time is simplified considerably as a result.

The measuring device comprises, in particular, a two-dimensional sensor. It can also comprise one or a plurality of sensor lines or an arrangement, in particular a two-dimensional arrangement, of individual sensors. In particular, a CCD camera can serve as measuring device.

The number of measurement points can be in the thousands. It is substantially determined from the dimensions of the object field and the pixel size of the sensor. It results, in particular, from the ratio of the size of the area illuminated on the sensor to the pixel size of the sensor.

The number of measurement values, in particular intensity values, detected in a single measurement step is in particular at least 100, in particular at least 200, in particular at least 300, in particular at least 500, in particular at least 1000, in particular at least 2000, in particular at least 3000, in particular at least 5000, in particular at least 10000. It is usually less than 10⁹.

Provision is made, in particular, for detecting the intensity distribution over the entire illumination field with the measuring device. The multiplicity of detected measurement values is also referred to overarchingly as detected intensity distribution.

The measuring device is sensitive in particular in the wavelength range of the illumination radiation used for the measurement. It is sensitive in particular in the EUV and/or DUV range. In principle, the optical components of the projection exposure apparatus can also be examined using radiation having a wavelength that deviates from the operating wavelength.

The sensor of the measuring device has, in particular, dimensions which correspond to those of the object field or to those of the image field of the projection exposure apparatus or are of at least the same magnitude as these.

In principle, the measuring device can also comprise a plurality of sensors, in particular a plurality of sensors arranged next to one another. Furthermore, it is also possible to use a sensor whose dimensions are smaller than those of the object field or those of the image field of the projection exposure apparatus. The sensor can be displaced over the desired field regions in order to detect the measurement values.

The image field can have dimensions of a few hundred square millimeters, for example. It has for example a length of 26 mm and a width of 8 mm.

The pixels of the sensor can for example have a diameter of a few micrometers, for example of approximately 15 μm. Depending on requirements, higher or lower resolutions are likewise possible and advantageous, if appropriate.

In accordance with one aspect of the invention, the measuring device for detecting the intensity distribution of the illumination radiation is arranged in a reticle plane or a wafer plane. In this case, the reticle plane coincides in particular with the object plane of the projection exposure apparatus. In this case, the wafer plane coincides in particular with the image plane of the projection exposure apparatus, in particular the projection optical unit thereof.

The measuring device is arranged in particular in a freely accessible region of the projection exposure apparatus. It can be arranged in particular between two closed submodules of the projection exposure apparatus. It can be arranged in particular in the region between the illumination optical unit and the projection optical unit. It can also be arranged in the region in the beam path downstream of the projection optical unit.

In accordance with a further aspect of the invention, the measuring device can also comprise one or more additional sensors arranged at a distance from a field plane of the projection exposure apparatus. It can comprise in particular one or more sensors arranged in a pupil plane of the projection exposure apparatus or at least near the pupil. It is thereby possible to obtain additional information that may be useful for determining the predicted values of the optical parameter. The measuring device can also be configured to capture a focus stack with a plurality of images that are captured at positions that are offset, that is to say spaced apart, with respect to one another in the direction of the beam path of the projection exposure apparatus.

In accordance with a further aspect of the invention, at least 10% of the area of the object field is used for detecting the intensity distribution. The area of the object field that is used for detecting the intensity distribution is in particular at least 20%, in particular at least 30%, in particular at least 50%, in particular at least 70%, in particular at least 90%.

It is thereby possible to achieve a relatively high degree of oversampling, in particular in comparison with the prior art with pupil measurements. It is possible in particular that a plurality of measurement values exist for a given area region, in particular that a specific area region on the surface of one of the optical components of the projection exposure apparatus is sampled by a plurality of illumination channels. This makes possible, in particular, a more reliable determination of the predicted values of the optical parameter, a higher spatial resolution and a better separability of the measured change over the optical elements considered.

In accordance with a further aspect of the invention, the number of field points at which the intensity of the illumination radiation is detected with the measuring device is greater than 100, in particular greater than 1000. It can be in particular greater than 10000, in particular greater than 100000. It is usually less than 10⁸. The number of field points at which the intensity of the illumination radiation in the object field is measured, can be in particular of the same magnitude as the number of pixels of the measuring device. It is dependent in particular on the pixel size, i.e. the resolution of the measuring device.

In accordance with a further aspect of the invention, at least 10%, in particular at least 20%, in particular at least 30%, in particular at least 50%, in particular at least 70%, of the illumination radiation guided to the field plane is detected by the measuring device. This, too, results in an improved determination of the predicted values.

If the measuring device is arranged in the region of the image plane of the projection exposure apparatus, these indications can correspondingly relate to the intensity distribution of the illumination radiation in the image field.

In accordance with a further aspect of the invention, the illumination optical unit has at least one faceted element having a multiplicity of different facets for generating different radiation beams, wherein at least one subset of the facets is switchable.

In this case, the switchability of the facets can be achieved by a displacement, in particular a tilting, thereof and/or by shading thereof using suitable stops.

The different radiation beams form different illumination channels.

Preferably, the illumination optical unit comprises two to six faceted elements, wherein a respective facet of the first faceted element is assigned to a facet of the second faceted element and an illumination channel for illuminating the object field within a specific angle of incidence or an angle-of-incidence distribution is in each case formed as a result.

The facets of the first faceted element are displaceable in particular in such a way that they can be assigned to different facets of the second faceted element. The illumination-angle distribution of the illumination of the object field can be influenced flexibly as a result. For further details, reference should be made to the previously known prior art, for example DE 10 2010 062 763 A1 already mentioned.

It is also possible for one or both of the faceted elements to be embodied as a micromirror array. In this case, individual facets can be embodied flexibly by a plurality of individual mirrors. For details, reference should be made, in representative fashion, to WO 2009/100 856 A1.

In accordance with a further aspect of the invention, a predefined selection of illumination channels is used for impinging on the measuring device with illumination radiation.

Provision can be made, in particular, for using in each case only a proper subset of the simultaneously possible illumination channels for impinging on the measuring device with illumination radiation.

Particularly if one or both of the faceted elements is/are embodied as a micromirror array, it is possible to choose a grouping in the measurement in which the total number of measurements is minimized by as many micromirrors as possible being switched simultaneously in the object plane, without the object fields of the micromirrors overlapping.

By selecting the illumination channels used for impinging on the measuring device with illumination radiation, it is possible to achieve a diversification that may be useful for a more reliable determination of the predicted values.

In accordance with one aspect of the invention, in each case only a single illumination channel is used for impinging on the measuring device with illumination radiation. The measuring device can be impinged on in particular sequentially with illumination radiation from single illumination channels. It is also possible to use in each case two, three, four or more illumination channels for impinging on the measuring device with illumination radiation. The maximum number of illumination channels used for impinging on the measuring device with illumination radiation can be in particular less than n, in particular less than n−1, in particular less than n/2, in particular less than n/3, in particular less than n/4, in particular less than n/5, in particular less than n/10, in particular less than n/20, in particular less than n/50, in particular less than n/100, wherein n denotes the number of facets of the first faceted element of the illumination optical unit or the maximum number of facets of the first faceted element of the illumination optical unit that are able to be illuminated simultaneously with illumination radiation.

In accordance with a further aspect of the invention, the measuring device is impinged on with illumination radiation a number of times, wherein

the selection of the illumination channels/illumination settings used therefor is altered and/or

different measurement reticles are arranged in the object field and/or

an arrangement of at least one radiation-influencing element in the beam path of the illumination radiation is altered.

As a result, in a targeted manner, contributions by different optical components from among the optical components of the projection exposure apparatus, and the effect of a degradation thereof can be separated from one another.

Corresponding measures make it possible, in particular, in the projection optical unit, through higher orders of diffraction, to scan parts of the areas of the optical components that are not reached otherwise.

It is possible, for example, using a suitable reticle, to impinge on the pupil with a global tilt angle. The regions scanned on mirrors of the projection optical unit that are near the pupil can be influenced as a result.

In accordance with a further aspect of the invention, the detected intensity distribution of the illumination radiation in a field plane is normalized upon repeated impingements on the measuring device with illumination radiation. Momentary fluctuations of the radiation source, in particular of the total radiation power emitted by the latter, can be compensated for as a result.

For normalizing the intensity distribution, a specific illumination channel can be used as normalization channel. This need not always be the same illumination channel. For comparing two measurements, it suffices if the latter comprise at least one common illumination channel.

In principle, however, it is also possible, for normalizing the measurement, to couple out and separately detect part of the illumination radiation emitted by the radiation source.

In accordance with a further aspect of the invention, the reference values are determined from an intensity distribution detected with the measuring device, or using a model. The reference values can be determined in particular with a simulation of the system taking account of the material parameters, such as reflectivity data, for example, that are known from the literature and/or production and/or from concrete measurements on the system. The reference values can also be predefined. They may have been determined in some other way, for example.

In accordance with a further aspect of the invention, the surfaces over which the predicted values of the optical parameter are determined are selected from the following list: radiation source point (plasma region), reflection surface of a collector mirror, intermediate focal plane, reflection surface of a mirror of the illumination optical unit, in particular reflection surface of a field facet mirror, reflection surface of a pupil facet mirror and/or reflection surface of a mirror of a transfer optical unit of the illumination optical unit, in particular of a grazing incidence mirror (GI mirror), a UNICOM plane, a reticle plane, a reflection surface of a mirror of a projection optical unit, a stop plane, in particular for an aperture stop (NA blades, numerical aperture blades), a pellicle plane, a DGL membrane plane, and the plane in which the measuring device is arranged.

In principle, the predicted values can be determined over an arbitrary selection of the surfaces of the optical component of the projection exposure apparatus. It is possible, in particular, to determine predicted values for the optical parameter over the surfaces of all of the optical components of the projection exposure apparatus.

In this case, as explained in even greater detail below, the different contributions of the different components can be separated from one another.

In accordance with a further aspect of the invention, the deviations of the predicted values of the optical parameter from the reference values are determined over at least two of the specified surfaces. For this purpose, the deviations of the predicted values from the reference values on the specified surfaces are developed into suitable modes and the amplitudes thereof are adapted to the illumination light measured in the object plane. The amplitudes of low-frequency modes are preferably maximized during the adaptation. It has been found that the meaningfulness of the predicted values was able to be improved as a result.

Preferably, the deviations of the predicted values of the optical parameter from the reference values over the surfaces of all optical components of the illumination optical unit and/or of the projection optical unit are determined in this way from the adaptation of the illumination light measured in the object plane. It has been found that this is possible in particular on account of the oversampling of the measurement values detected by the measuring device.

In this way, the optical quality of all of the optical components of the projection exposure apparatus can be monitored and a possible degradation thereof can be detected.

In accordance with a further aspect of the invention, basis splines (b-splines) are used as modes for developing the deviations determined. This is done by calculating the signatures associated with the modes on the individual surfaces in the illumination light at the object plane and adapting the amplitudes to the measured illumination light.

It has furthermore been recognized that the resolution of the measuring device limits the practical minimum local resolution of the basis functions for developing the deviations determined for near-field mirrors.

For near-pupil mirrors of the projection optical unit, the size of the steps of the changes in the pitches of masks with a so-called dense lines structure for a dipole illumination setting determines the minimum local resolution for reflectivity changes.

Particularly for an illumination optical unit having switchable field facets and non-switchable, static pupil facets, reflectivity changes of the pupil facets can be detected by switching over the field facets.

In accordance with a further aspect of the invention, a software-based algorithm serves for determining the predicted values of the optical parameter over the at least one predefined surface from the detected intensity distribution and/or for determining the deviation of the predicted values of the optical parameter from reference values.

A further object of the invention is to provide a system for the characterization of at least one optical component of a projection exposure apparatus.

This object is achieved with a system comprising a measuring device for detecting an intensity distribution of illumination radiation in a field plane of the projection exposure apparatus, a storage device for storing reference values of an optical parameter over at least one predefined surface and a data processing apparatus for determining a deviation of predicted values of the optical parameter over the at least one predefined surface from the reference values, in particular ratios of the measurement values to the reference values, from the detected intensity distribution.

The system is, in particular, a system for carrying out the method in accordance with the preceding description.

In particular, a software-based algorithm serves for determining the deviation of the predicted values of the optical parameter from the reference values. The data processing apparatus comprises, in particular, a software product for carrying out said algorithm.

The algorithm comprises in particular one or more filtering steps. As a result, in particular the contribution of low-frequency modes over the predefined surfaces can be increased, in particular maximized.

The system can comprise one or more diversification devices. In particular, a device for the variation of an illumination setting and/or the use of specific, in particular different, exchangeable measurement masks and/or the arrangement and/or displacement of a radiation-influencing element in the beam path of the illumination radiation can serve as diversification devices. In particular, a filter and/or a stop can serve as radiation-influencing element. The radiation-influencing element can be arranged in particular near the field or near the pupil. In principle, it is possible to carry out a field manipulation and/or a pupil manipulation in an arbitrary region, in particular in an arbitrary plane.

A further object of the invention is to improve a microlithographic projection exposure apparatus. This object is achieved with a projection exposure apparatus comprising a system for characterizing at least one optical component of the projection exposure apparatus in accordance with the preceding description.

The advantages are evident from those already described.

Further subject matter of the present invention is a software product for determining the predicted values of the optical parameter over the at least one predefined surface from the detected intensity distribution.

### BRIEF DESCRIPTION OF THE DRAWINGS

Further features and advantages of the invention will become apparent from the description of exemplary embodiments with reference to the figures. In the figures:

FIG. 1 schematically shows an illustration of the subsystems of a projection exposure apparatus,

FIG. 2 schematically shows an exemplary illustration of the optical components of a projection exposure apparatus and of the beam path of the illumination radiation in said apparatus,

FIG. 3 shows a schematic sequence of the details of the method step of detecting the measurement data in accordance with one of the methods shown below,

FIG. 4 schematically shows a sequence of the algorithm for determining predicted values of an optical parameter from the detected measurement values,

FIG. 5 shows a schematic sequence of the details of the method step of detecting the measurement data in accordance with one alternative.

### DETAILED DESCRIPTION

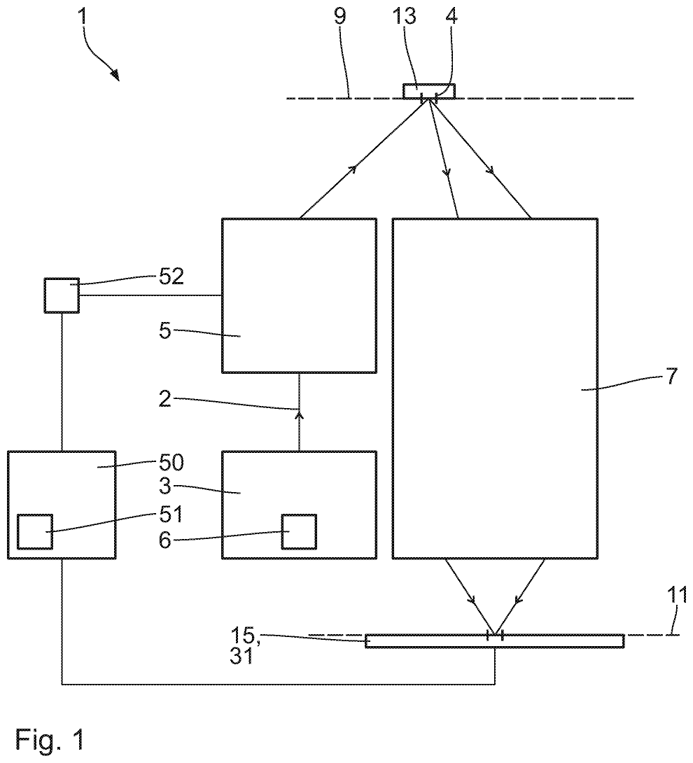

FIG. 1 shows a schematic illustration of the subsystems of a projection exposure apparatus 1.

The projection exposure apparatus 1 comprises, inter alia, a radiation source module 3, which is also referred to as a source collector module (SoCoMo). Furthermore, the projection exposure apparatus 1 comprises an illumination optical unit 5 for transferring illumination radiation 2 from the radiation source to an object field 4 in an object plane 9. The object plane 9 is a field plane of the projection exposure apparatus 1. A structure-bearing mask, referred to as a reticle 13, can be arranged in the object plane 9.

Furthermore, the projection exposure apparatus 1 comprises a projection optical unit 7. With the aid of the projection optical unit 7, the reticle 13 can be imaged onto a substrate, in particular in the form of a wafer 15. The wafer 15 is arranged in an image plane 11 of the projection optical unit 7. The image plane 11 is likewise a field plane of the projection exposure apparatus 1.

The illumination optical unit 5 and the projection optical unit 7 comprise a multiplicity of optical components. In principle, the optical components of the projection exposure apparatus 1 can be embodied both in reflective fashion and in refractive fashion. Combinations of refractive and reflective optical components within the projection exposure apparatus 1 are also possible.

The projection exposure apparatus 1 can be an EUV projection exposure apparatus, in particular. In this case, the radiation source 6 is an EUV radiation source for generating illumination radiation 2 having a wavelength in the range of 5 nm to 15 nm.

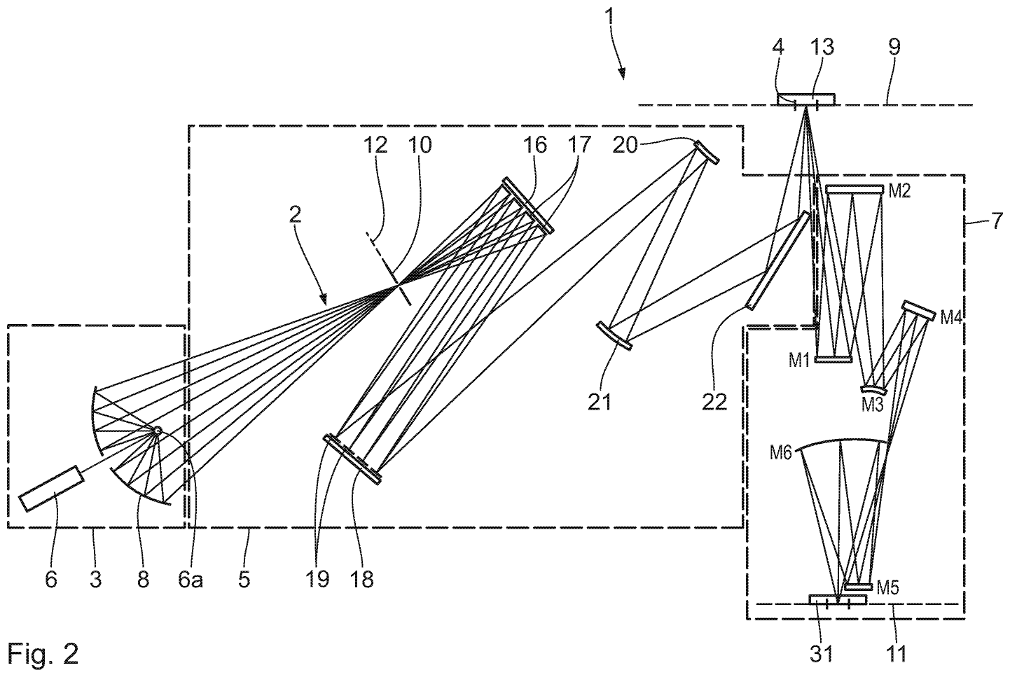

FIG. 2 schematically illustrates an arrangement of the components of the projection exposure apparatus 1 in greater detail by way of example.

The radiation source module 3 comprises the radiation source 6, which is embodied as a laser plasma source. Alternative embodiments of the radiation source 6, in particular alternative EUV sources, are likewise possible.

The radiation source module 3 furthermore comprises a collector mirror 8.

With the aid of the collector mirror 8, the illumination radiation 2 can be focused at an intermediate focus 10 in an intermediate focal plane 12.

The intermediate focal plane 12 can form the transition from the radiation source module 3 to the illumination optical unit 5. The illumination optical unit 5 can be closed off toward the outside in particular in a vacuum-tight manner. In particular, it can be arranged in an evacuatable housing.

The illumination optical unit 5 comprises a first faceted element 16 having a multiplicity of first facets 17. The first faceted element 16 is a field facet mirror, in particular. The first faceted element 16 is arranged in particular in a field plane of the projection exposure apparatus 1 or in a conjugate plane with respect thereto. The facets 17 are also referred to as field facets.

The illumination optical unit 5 furthermore comprises a second faceted element 18 having a plurality of facets 19. The second faceted element 18 is a pupil facet mirror, in particular. The facets 19 are correspondingly also referred to as pupil facets.

An arrangement of the first faceted element 16 and/or of the second faceted element 18 that deviates from this is likewise possible. For details of a corresponding arrangement, also referred to as a specular reflector, reference should be made by way of example to US 2006/0132747 A1.

During operation of the projection exposure apparatus 1, in order to form different illumination channels, each of the facets 17 of the faceted element 16 can be assigned to one of up to five different facets from among the facets 19 of the second faceted element 18. Moreover, the illumination optical unit 5 comprises three mirrors 20, 21, 22. The mirrors 20, 21, 22 form a transfer optical unit.

The mirror 22 is embodied in particular as a grazing incidence mirror (so-called GI mirror, or simply just G mirror).

The projection optical unit 7 comprises six mirrors, which are designed by M₁ to M₆ in accordance with their sequence in the beam path of the projection exposure apparatus 1.

The projection optical unit 7 can also comprise a different number of mirrors Mᵢ. It can comprise in particular four, eight or ten mirrors Mᵢ.

The arrangement of the optical components of the projection exposure apparatus 1, in particular of the radiation source module 3, of the illumination optical unit 5 and of the projection optical unit 7, in FIG. 2 should be understood to be purely by way of example. Numerous different embodiments for different arrangements of the components of the projection exposure apparatus 1 are known from the prior art.

During operation of the projection exposure apparatus 1, a respective one of the facets 19 of the second faceted element 18 is assigned to the active facets 17 of the first faceted element 16, that is to say the facets which contribute to the illumination of the object field 4 with illumination radiation 2. The facets 17, 19 assigned to one another in each case form an illumination channel for illuminating the object field 4 with a specific illumination angle or an illumination-angle distribution. The totality of the illumination channels is also referred to as an illumination setting.

The assignment of the first facets 17 to the second facets 19 is preferably switchable. For this purpose, the first facets 17 are preferably displaceable, in particular tiltable. They can also be tiltable in such a way that the illumination radiation 2 incident on them no longer contributes to the illumination of the object field 4. For details of the switchability of the facets 17, reference should in turn be made to previously known prior art, in particular WO 2011/154 244 A1.

The first faceted element 16 decomposes the illumination radiation 2 into a multiplicity of different beams of rays.

With the aid of the facets 17 of the first faceted element 16, the image of the radiation source 6 at the intermediate focus 10 is imaged onto the facets 19 of the second faceted element 18.

For their part, the facets 19 of the second faceted element 18 image the facets 17 of the first faceted element 16 into the object field 4.

The images of the facets 17 of the first faceted element 16 are superimposed in the object plane 9. They overlap at least partly, in particular completely, in the object plane 9. In accordance with an alternative embodiment, it is also possible for at least one portion of the first facets 17 of the first faceted element 16 to be embodied in such a way that their images in the object plane 9 are free of overlap.

The beams of rays that are produced by the facets 17 of the first faceted element 16 have specific regions of incidence on all downstream optical components of the projection exposure apparatus 1, which regions can be determined from the design of the subsystems of the projection exposure apparatus 1, in particular from the design of the illumination optical unit 5 and the design of the projection optical unit 7, for example with the aid of ray tracing.

In this case, different illumination channels can illuminate overlap-free regions on specific components of the projection exposure apparatus 1. This is the case in particular for near-pupil components of the projection exposure apparatus 1. In the case of components arranged near the field, an overlap of the regions of incidence can occur.

The optical components of the projection exposure apparatus 1, in particular of the radiation source module 3, of the illumination optical unit 5 and of the projection optical unit 7, have radiation-influencing surfaces, in particular radiation-reflecting surfaces, the course of which is known from the design of the respective subsystems.

A description is given below of a method that serves for determining, in particular for monitoring, the reflectivity of the optical components of the projection exposure apparatus 1 or the change thereof.

After the projection exposure apparatus 1 has been provided, a measuring device 31 is provided. The measuring device 31 is arranged in a field plane of the projection exposure apparatus 1, in particular in the region of the image plane 11 or in the region of the object plane 9.

The corresponding regions are freely accessible, in particular. They are also freely accessible in particular during operation of the projection exposure apparatus 1. The measuring device 31 can be arranged in particular outside the subsystems of the projection exposure apparatus 1. The subsystems of the projection exposure apparatus 1, in particular the radiation source module 3, the illumination optical unit 5 and the projection optical unit 7, can thus remain in the state ready for operation, even when the measuring device 31 is arranged in a field plane of the projection exposure apparatus 1.

The step of providing the measuring device 31 and arranging the latter in the beam path of the projection exposure apparatus 1 is illustrated in the figures in each case as initial step 32 of the method.

After the measuring device 31 has been provided and arranged in a field plane of the projection exposure apparatus 1, the object field 4, in particular the measuring device 31 arranged in the region of the object field 4 or the reticle 13 arranged there, is impinged on with illumination radiation 2.

For carrying out the method, the reticle 13 used can be a mask having measurement structures provided specifically for this purpose. This will be explained in even more detail below.

An intensity distribution of the illumination radiation 2 in the field plane is then detected with the measuring device 31 in a first measurement process 33. For this purpose, a specific illumination channel is switched on in a switching step 35.

In this alternative, a specific illumination setting is selected. Individual illumination channels of this setting are then switched on successively in the switching steps 35. The measurements in the measurement steps 33 are thus carried out in each case with illumination of the object field 4 with a single illumination channel. The stored data can thus be unambiguously assigned to the different illumination channels.

Instead of the illumination of the object field 4 with single illumination channels, combinations of a plurality of illumination channels of the predefined illumination setting can also be switched on in the switching steps 35. This may result in a time saving.

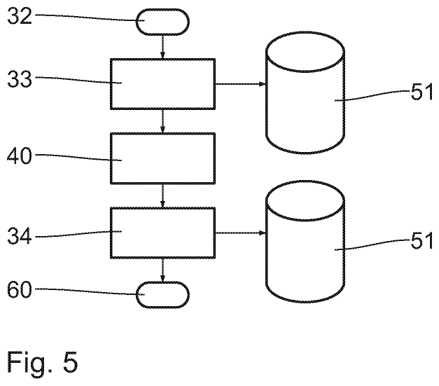

Instead of a single, specific illumination setting being predefined and switched by the single illumination channels thereof or combinations of same, the measurement steps 33i can also be carried out with different illumination settings. This alternative is illustrated schematically in FIG. 5.

With the aid of the measuring device 31, the intensity distribution of the illumination radiation 2 in the field plane is detected in a locally resolved manner. In particular, a two-dimensional distribution of the intensity of the illumination radiation 2 in the field plane is detected.

The measured intensity distribution is stored in a storage device 51. It can be stored as a bitmap file, in particular. It is stored in particular together with the information about the illumination channels selected for illuminating the object field 4.

In accordance with one advantageous alternative, the intensity distribution detected in the measurement step 33 is normalized as a function of the radiation dose of the illumination radiation 2.

By way of example, the measuring device 31 can be a CCD camera. The measuring device 31 comprises in particular a sensor having more than 1000, in particular more than 10000, in particular more than 30000, in particular more than 50000, in particular more than 100000, in particular more than 200000 pixels. The measuring device 31 can have in particular up to a plurality of megapixels (10⁶ pixels).

From the detected intensity distribution, after providing design data of the projection exposure apparatus 1 with the aid of an algorithm 36 (see FIG. 4) it is possible to determine values of an optical parameter, in particular of the reflectivity, of the optical components of the projection exposure apparatus 1, which can be used as reference values, in particular for determining the change in the reflectivity of the optical components of the projection exposure apparatus 1.

A subsequent decision step 39 involves checking whether the detected intensity distribution is sufficient for the envisaged purpose, in particular for determining predicted values for a predefined optical parameter over predefined surfaces of the optical components of the projection exposure apparatus 1 with a desired resolution. If this is the case, the data acquisition can be ended (end 60). Otherwise, a further switching step 35 is carried out for switching on a new selection of illumination channels.

In principle, the number of implemented switching steps 35 and subsequent measurement steps 33 is limited only by the number of possibilities for combination of different illumination channels.

At a later point in time, the measurement steps 33 can be repeated with an identical selection of illumination channels. From a comparison of the detected measurement data, it is then possible to determine a change in the optical parameter over the predefined surfaces of the optical components of the projection exposure apparatus 1.

The values stored in the storage device 51 during the first data acquisition can serve as reference values for later measurements. As an alternative thereto, the reference values can be determined with the aid of a model or be predefined externally.

A description is given below of the case where the first measurement values serve as reference values and a second measurement process is provided at a later point in time.

With reference to FIG. 4, a description is given below of an algorithm 36 for determining predicted values of the optical parameter over the predefined surfaces of the optical components of the projection exposure apparatus 1 and, in particular, the determination of a deviation of the predicted values of the optical parameter from reference values.

The data stored in the storage device 51 serve as a starting point for determining a deviation of the predicted values of the optical parameter from reference values. As already described, said data are, in particular, the locally resolved intensity profiles of the illumination radiation 2 in a field plane, said intensity profiles having been detected in different measurement steps 33. The stored values are, in particular, channel-resolved intensities in the object plane 9 at least two different points in time, for example a current point in time and an earlier point in time serving as a comparison value, i.e. as a reference value. However, reference data derived using a model and/or a simulation and/or in some other way can also be stored in the storage device 51.

A first processing step 24 involves determining ratios Rₙ^{1.2}(x₀, y₀) of the bitmaps of the intensities of the different measurement data for identical illumination channel combinations. In particular, suitably normalized bitmaps are used in this case.

A second processing step 25 then involves optimizing weighting factors a_{s,m}, such that the formula reconstruction error resulting from the following formula is minimized:

$${min}_{a } {\sum }_{n} \int \int {dx}_{o} {dy}_{o} ‖ {\prod }_{s} {H}_{n , s}^{- 1} ( {\sum }_{m} {a}_{s , m} {b}_{s , m} ( {x}_{s} , {y}_{s} ) ) - {R}_{n} ( {x}_{o} , {y}_{0} ) ‖$$

Herein H_{n,s} indicates the mapping of the object field coordinates (x₀, y₀) on the coordinates (xₛ,yₛ) on a surface s of an optical component of the projection exposure apparatus 1 during an illumination with the illumination channel n, H_{n,s}(x₀, y₀)=(xₛ, yₛ). The inverse mapping is designated by

H_{n,s}⁻¹.

b_{s,m}(xₛ, yₛ) are the basis modes numbered consecutively with the index m which were selected for the surface s. In particular, b-splines can serve as basis modes b_{s,m}.

The function H_{n,s} can be determined with the aid of a ray tracing method, in particular a backward ray tracing method. As a simplification here the angle dependence of the function H_{n,s} can be disregarded. It is possible, in particular, to use only the rays through the geometric area centroids of the pupil facets during the backward ray tracing.

The design data—predefined as known—of the projection exposure apparatus 1 or the subsystems thereof are taken into account in order to determine the function H_{n,s}.

It has been found that when the object field 4 is illuminated with only a small number of illumination channels, in particular with single illumination channels in each case, a corresponding backward ray tracing method is suitable for determining the function H_{n,s}.

The second processing step 25 is an optimization method, in particular. This optimization method involves determining a distribution of spatial modes having the lowest possible frequency for developing the optical parameter Tₛ over the surface s of the predefined optical component of the projection exposure apparatus 1, which leads to a minimization of the residual errors over the predefined surfaces s.

A development step 26 involves developing the optical parameter Tₛ(xₛ, yₛ) for each of the predefined surfaces s of the optical components of the projection exposure apparatus 1 according to the basis modes b_{s,m}(xₛ, yₛ) chosen. In order to determine the changes in the optical parameter Tₛ^{1,2}(xₛ, yₛ), it is sufficient to predefine a basis system, i.e. the basis modes b_{s,m}(xₛ, yₛ). The absolute values of the optical parameter Tₛ(xₛ, yₛ) need not necessarily be determined.

In a third processing step 27, the optimized weights aₒₚₜ are used to reconstruct a change Tₛ^{1,2}(xₛ, yₛ) in the optical parameter between the two measurements on the surface s. The change can be represented as follows:

$${T}_{s}^{1 , 2} ( {x}_{s} , {y}_{s} ) = {\sum }_{m} {a}_{s , m ; opt} {b}_{s , m} ( {x}_{s} , {y}_{s} )$$

The values resulting therefrom are stored in a storage device 51a. The storage devices 51 and 51a can be physically accommodated in a common component.

By comparing the optimized weighting factors aₒₚₜ for intensity profiles from different measurement steps 33ᵢ, 33ⱼ, it is possible to determine changes in the optical properties, in particular a deviation thereof from reference values. In particular a degradation of the optical properties, in particular of the reflectivity, of the optical components of the projection exposure apparatus 1 can be determined from the deviation.

With the aid of the method described, in particular local changes, in particular non-uniform, relative changes, in the optical parameter, in particular the reflectivity, of the optical components of the projection exposure apparatus 1 can be determined and be assigned in particular to a specific optical component of the projection exposure apparatus 1.

In order to scan all components of the projection exposure apparatus 1 as completely as possible, it can be expedient to switch on as many as possible, in particular at least a minimum number, in particular all, of the different illumination channels individually or in combination with one another in sequential switching steps 35ᵢ. This is advantageous in particular for scanning, i.e. for illuminating, near-pupil and/or intermediate optical surfaces.

Provision can also be made for switching different, in particular complementary, illumination settings in switching steps 35ᵢ. By way of example, one half of the pupil can be illuminated in a first switching 35₁ step, while the other half of the pupil is illuminated in a second switching step 35₂. Illumination settings of this type are also referred to as complementary settings. An x-dipole setting and a complementary y-dipole setting can be involved, for example.

Preferably, in this case, at least one common channel is measured in both settings. This can be used for normalization purposes.

In accordance with the alternative illustrated schematically in FIG. 5, two measurement steps 33, 34 are provided. The measurement steps 33, 34 are carried out using the same illumination setting, but with different reticles 13ᵢ, 13ⱼ. By way of example, the reticle 13ᵢ can have vertical structures, in particular dense vertical lines, and the reticle 13ⱼ can have horizontal structures, in particular dense horizontal lines.

A diversification 40 is generally carried out between the measurement steps 33 and 34.

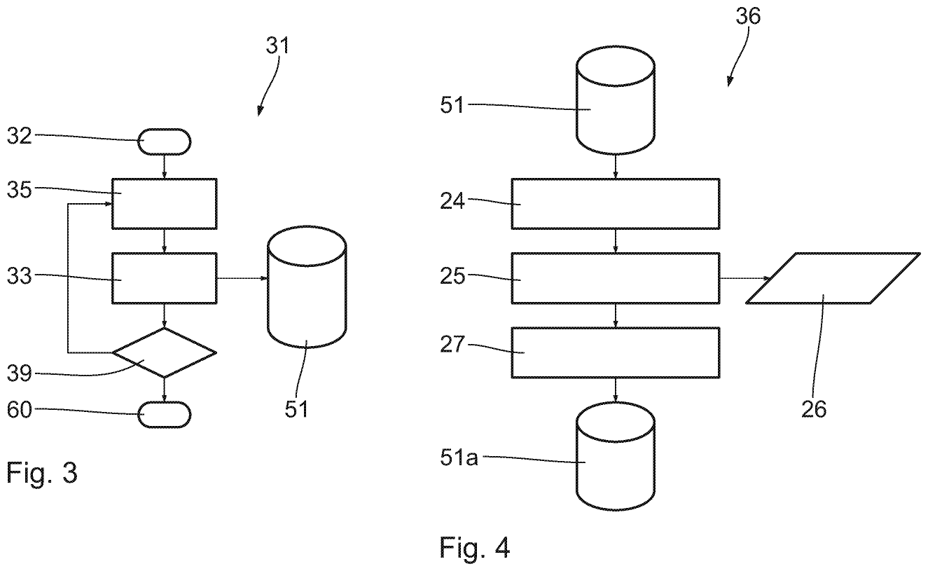

The switching steps 35ᵢ and the decision steps 39ᵢ are not illustrated in FIG. 5 for simplification. These steps can be provided correspondingly as in the case of the flowchart in accordance with FIG. 3. Provision can once again be made, in particular, for predefining a specific illumination setting and switching it individually with the illumination channels or a combination thereof. An illumination of the reticles 13ᵢ, 13ⱼ with different illumination settings is also possible. For details, reference is made to the preceding description.

The diversification 40 can be helpful in order that changes in the optical parameter can be better assigned to specific components of the projection exposure apparatus 1.

In addition to the already illustrated possibilities of changing the illumination setting and using different measurement reticles 13_{i,} 13ⱼ a radiation-influencing element can also be arranged as diversification device in the beam path of the illumination radiation 2 or its arrangement can be altered. In addition, it is possible, in principle, to exchange one or more of the optical components of the projection exposure apparatus 1. This can be expedient particularly when an impairment (degradation) of the corresponding optical component is suspected.

Here the object field 4 is sequentially illuminated by a single illumination channel in each case.

In accordance with one alternative, provision can be made for using only a selection of the illumination channels for illuminating the object field 4. This can result in a considerable time saving.

By way of example, it is possible to use only a maximum of 1000, in particular a maximum of 500, in particular a maximum of 300, in particular a maximum of 200, in particular a maximum of 150, in particular a maximum of 30, in particular a maximum of 20, in particular a maximum of ten, in particular a maximum of five, in particular a maximum of three, in particular a maximum of two, different illumination channels for sequentially illuminating the object field 4. In principle, a single illumination of the object field 4, that is to say the use of a single illumination setting, in particular of a single illumination channel, for illuminating the object field 4 and thus a single measurement step 33 can also be sufficient.

In accordance with a further alternative (not illustrated), provision is made for coupling out part of the illumination radiation 2 emitted by the radiation source 6 in order to normalize the measurement data. Said part of the illumination radiation 2 can be guided past the optical components of the projection optical unit 7, in particular. In principle, it can also be guided past the optical components of the illumination optical unit 5 or at least a selection thereof. It is possible, for example, to use one or more of the facets 17 of the first faceted element 16 for coupling out illumination radiation 2 from the beam path of the projection exposure apparatus 1.

A separate sensor can be provided for detecting the illumination radiation coupled out, in particular the intensity thereof.

An outline summary of further details and aspects of the method described above is described below. These details relate, unless indicated otherwise, to all of the various alternatives described above.

The method is applicable in situ, that is to say in a fully assembled projection exposure apparatus 1 ready for operation. In particular, it is not necessary to dismantle the projection exposure apparatus 1 or to demount one of the subsystems thereof in order to apply the method. The downtime of the projection exposure apparatus 1 is considerably reduced as a result.

The method can be carried out in particular directly by the end user of the projection exposure apparatus 1. It can be carried out in particular under the real conditions usually prevailing there.

The method is applicable online, in particular. It results in a statement about the optical parameter, in particular the reflectivity, of the optical components of the projection exposure apparatus 1 in real time.

With the aid of the method, it is possible, in particular, to ascertain an impairment (degradation) of the mirrors, in particular also of the grazing incidence mirrors (GI mirrors).

It is possible, in particular, to determine the reflectivity of mirrors arranged outside a field or pupil plane of the projection exposure apparatus 1, or the change thereof.

The method makes it possible, in particular, to carry out preventive maintenance work. An unnecessary exchange of optical components can be prevented.

The method can in particular very reliably detect effects on a length scale in the millimeters or centimeters range. This corresponds to the customary length scale of degradation effects.

By way of the method, in particular a plurality, in particular all, of the optical components of the projection exposure apparatus 1 can be monitored, in particular a degradation thereof can be ascertained, in particular can be assigned to a specific one of the optical components of the projection exposure apparatus 1.

All of the facets 17 of the first faceted element 16 and/or all of the facets 19 of the second faceted element 18 can be used in the method. It is also possible to use only a predetermined selection of the facets 17 and/or of the facets 19.

By providing and using different measurement reticles 13ᵢ, 13ⱼ, it is possible to differentiate effects attributable to a degradation of the optical components of the illumination optical unit 5 very simply and reliably from effects attributable to a degradation of the components of the projection optical unit 7.

With the use of different reticles 13ᵢ, 13ⱼ, the function H_{n,s} changes in particular for surfaces s which lie in the projection optical unit 7.

It is also possible to use further diverse diversification devices in order to differentiate effects of the change in the optical parameter, in particular the reflectivity, of different optical components from among the optical components of the projection exposure apparatus 1 from one another.

The intensity distribution of the illumination radiation is detected in particular over an area corresponding to at least 10%, in particular at least 20%, in particular at least 30%, in particular at least 50%, in particular at least 70%, in particular at least 90%, of the area of the object field 4 and/or of the image field of the projection exposure apparatus 1, depending on the field plane in which the measuring device 31 is arranged.

The number of measurement values detected here with the measuring device 31 corresponds precisely to the ratio of the area illuminated on the sensor of the measuring device 31 to the area of the individual sensor elements (pixel size). The number of data points per measurement can be in particular more than 1000, in particular more than 10000, in particular more than 100000, in particular more than 200000. If the regions which are illuminated by different illumination channels on the surface s of a specific optical component of the projection exposure apparatus 1 overlap, this can lead to oversampling.

The pixel size of the sensor of the measuring device 31 is in particular in the range of 1 μm² to 10000 _{μm}², in particular in the range of 10 _{μm}² to 1000 _{μm}², in particular in the range of 100 _{μm}² to 500 _{μm}².

The measuring device 31 is preferably sensitive in the wavelength range in the radiation source 6 which is provided for the normal operation of the projection exposure apparatus 1. The measuring device 31 is sensitive in particular in the EUV and/or DUV range.

It is also possible, in principle, to use a specific measurement radiation source for characterizing the optical components of the projection exposure apparatus 1 with the aid of the method described above. The measurement radiation source can emit measurement radiation in a wavelength range which deviates from that of the illumination radiation 2 provided for the operation of the projection exposure apparatus 1.

In accordance with a further aspect of the invention, various illumination settings which are particularly advantageous for the characterization of selected optical components from among the optical components of the projection exposure apparatus 1 are determined before the method is carried out. It is possible, in particular, to predefine a predefined number of different measurement illumination settings. The latter can be selected and set with the aid of a suitable control device 52. This can result in a considerable time gain. The number of measurement illumination settings can be in particular in the range of 1 to 100, in particular in the range of 2 to 50, in particular in the range of 3 to 30.

A filter element can serve as diversification device. A diversification device can preferably be arranged in proximity to the object plane 9 or in proximity to the image plane 11. In principle, it can also be arranged in an arbitrary, freely accessible region in the beam path of the projection exposure apparatus 1. In particular, the intensity distribution of the illumination radiation 2 on specific optical components from among the optical components of the projection exposure apparatus 1 can be influenced in a targeted manner with such a diversification device.

The reference values for the optical parameter of the different optical components of the projection exposure apparatus 1 can be determined from the design data of the subsystems of the projection exposure apparatus 1 with the aid of a model or a simulation.

The reference values can also be predefined. They can be stored in particular in a storage device 51 of a data processing apparatus 50 of a system for carrying out the method described above.

The data processing apparatus 50 is connected to the measuring device 31 in a signal-transmitting manner.

The data processing apparatus 50 is connected to the control device 52 in a signal-transmitting manner. The control device 52 is connected to the illumination optical unit 5, in particular the first faceted element 16 and/or the second faceted element 18, in a signal-transmitting manner.

The control device 52 can additionally be connected to further diversification devices in a signal-transmitting manner.

As an alternative thereto, it is possible to determine reference values with the aid of a separate measurement step 33.

Model approaches for the dependence of the intensity distribution and/or locally resolved reflectivity can be predefined as a boundary condition for the algorithm 36. In particular, a radial dependence of the far field can be predefined. In particular, a two-dimensional Gaussian distribution can serve for describing the intensity distribution of the far field.

Provision can be made, in particular, for referencing the measurement data to the predefined far field through the function H_{n,s} where s=far field. For this purpose, the measurement values are divided by the known contribution of the far field to the measurement values and then the far field is extracted from the product over all system surfaces s. In principle, this is also possible with the other surfaces s of the optical components of the projection exposure apparatus 1, provided that the corresponding information is present. In particular, if the transmission distribution of a specific surface s at two system instants is known, the respective contribution can be divided out in order to better determine the contributions, in particular the degradation, of the other surfaces.

The relative reflectivity over all components of the projection exposure apparatus 1 can then be determined. In particular, a software-protected algorithm can be used for this purpose. In particular, a backward ray tracing method can be used for determining the reflectivity over all components of the projection exposure apparatus 1.

As a boundary condition for the determination of the reflectivity distribution over the surfaces of the optical components of the projection exposure apparatus 1, it can be stipulated that the values in adjacent regions differ at most by a predefined maximum value (absolute) or at most by a predefined factor (relative).

With the aid of the method described above, it is also possible, in particular, to determine the profile of the reflectivity over the surface of optical components of the projection exposure apparatus 1 which are not arranged in a field plane or a pupil plane.

The optical components over whose surfaces the predicted values 37 of the optical parameter are determined can be selected from the following list: radiation source point 6a, collector mirror, intermediate focus aperture, first faceted element 16, second faceted element 18, mirror 20, mirror 21, mirror 22 of the transfer optical unit, a so-called UNICOM stop, the reticle 13 in the object plane 9, all mirrors Mᵢ of the projection optical unit 7, an aperture stop, a pellicle plane, a DGL membrane plane and the plane in which the measuring device is arranged.

The time for setting a new illumination setting is in the range of a few seconds. The total time expenditure for all of the first measurement steps 33ᵢ and of the second measurement steps 34ᵢ, respectively, is in the range of a few minutes. It is in particular less than a few hours, in particular less than one hour, in particular less than 30 minutes.

Substantially the entirety of the illumination radiation 2 incident on the near-field mirrors is used, in particular, in the present method. Accordingly, a large subset, in particular at least 10%, in particular at least 20%, in particular at least 30%, in particular at least 50%, in particular at least 70%, in particular at least 90%, of the pixels of the sensor device of the measuring device 31 is used.

A degradation of the optical components of the projection exposure apparatus 1 can be determined with the aid of measurements spaced apart in time with otherwise identical settings.

Additional use of different illumination settings enables the spatial resolution to be improved. It is possible, in particular, to separate the contributions of different regions of the optical components of the projection exposure apparatus 1 from one another.

Repeated measurement with identical illumination settings but different measurement reticles 13 makes it possible to differentiate between effects of the degradation of the components of the illumination optical unit 5 and those of the projection optical unit 7.

In accordance with a further exemplary embodiment, provision is made for measuring, in the measurement step 33, a pupil, in particular the distribution of illumination intensities over different illumination angles, rather than the intensity distribution in the object field 4. The pupil is measured in particular at a limited number of field points. The number of field points at which the pupil is measured is in particular at most 100, in particular at most 50, in particular at most 30, in particular at most 20. It is preferably in the range of 3 to 13.

For measuring the pupil, it is possible for example to arrange a stop structure, in particular having a plurality of pinholes, in the object field 4 or at least near the field. In this case, the measuring device 31 is arranged just downstream of the stop structure.

The algorithm 36 remains substantially unchanged in this case, the function H_{n,s} being replaced by a function P_{n,s}, which maps the pupil measured at a specific field point (x₀, y₀) onto the coordinates (xₛ, yₛ) on the surface s of the respective optical component of the projection exposure apparatus 1. Furthermore, it is possible to take account of both field measurements and pupil measurements during the monitoring of each optical component of the projection exposure apparatus 1.

The fact of whether the projection exposure apparatus 1, in particular its subsystems 5, 7, satisfy predefined criteria can be derived from the results stored in the storage device 51a. If the determined values of the optical parameter deviate from the desired values by more than predefined permissible maximum values for one or more of the optical components of the projection exposure apparatus 1, it is possible to determine whether this deviation is able to be corrected or compensated for with a measure that can be implemented online. If this is not the case, the corresponding optical component(s) should be exchanged.

What is claimed is:

1. A method for characterizing at least one optical component of a projection exposure apparatus, comprising:
providing a radiation source for generating illumination radiation,
providing an illumination optical unit for directing the illumination radiation from the radiation source to an object field,
providing a measuring device for detecting the illumination radiation generated by the radiation source,
arranging at least one constituent part of the measuring device in a field plane of the projection exposure apparatus,
directing the illumination radiation onto the object field,
detecting an intensity distribution of the illumination radiation in the field plane with the measuring device),
determining predicted values of an optical parameter over at least one predefined surface from the detected intensity distribution, and
determining an absolute or relative deviation of the predicted values of the optical parameter over the at least one predefined surface from reference values,
wherein:
said directing of the illumination radiation comprises directing the illumination radiation onto the measuring device a plurality of times,
the illumination optical unit has at least one faceted element having a multiplicity of different facets for generating different radiation beams, wherein at least one subset of the facets is switchable,
a predefined selection of illumination channels is used for directing the illumination radiation onto the measuring device, and
the different radiation beams form different ones of the illumination channels.

2. The method as claimed in claim 1, wherein the at least one optical component of the projection exposure apparatus is characterized in situ.

3. The method as claimed in claim 1, wherein said detecting of the intensity distribution comprises using at least 10% of an area of the object field.

4. The method as claimed in claim 1, wherein said directing of the illumination radiation onto the measuring device a plurality of times comprises directing the illumination radiation with the same selection of the illumination channels.

5. The method as claimed in claim 1, wherein
the selection of the illumination channels used for said directing is altered and/or
different measurement reticles are arranged in the object field and/or
an arrangement of at least one radiation-influencing element in the beam path of the illumination radiation is altered.

6. The method as claimed in claim 1, wherein the detected intensity distribution of the illumination radiation in the field plane is normalized upon repeated impingements of the illumination radiation onto the measuring device.

7. The method as claimed in claim 1, wherein the reference values are determined or predefined from an intensity distribution detected with the measuring device or with a model.

8. The method as claimed in claim 1, wherein the surfaces over which the predicted values of the optical parameter are determined are selected from the following list: radiation source, reflection surface of a collector mirror, intermediate focal plane, reflection surface of a field facet mirror, reflection surface of a pupil facet mirror, reflection surface of a mirror of a transfer optical unit of the illumination optical unit, a UNICOM plane, a reticle plane, a reflection surface of a mirror of a projection optical unit, a stop plane, a pellicle plane, a DGL membrane plane, a wafer plane, and a plane in which the measuring device is arranged.

9. The method as claimed in claim 8, wherein the reflection surface of the mirror of the transfer optical unit of the illumination optical unit is a grazing incidence mirror, and wherein the stop plane is an aperture stop.

10. The method as claimed in claim 8, wherein the deviations of the predicted values of the optical parameter from the reference values on at least two of the surfaces specified are developed into suitable modes, and wherein the amplitudes thereof are adapted to the intensity distribution of the illumination radiation detected with the measuring device, wherein the amplitudes of low-frequency modes are maximized during the adaptation.

11. The method as claimed in claim 10, wherein B-splines are used as modes for developing the developed deviations.

12. The method as claimed in claim 1, further comprising a software-based algorithm for determining the predicted values of the optical parameter over the at least one predefined surface from the detected intensity distribution and/or for determining the deviation of the predicted values of the optical parameter from the reference values.

13. A system for in-situ characterization of at least one optical component of a projection exposure apparatus, comprising:
a measuring device configured to detect an intensity distribution of illumination radiation in a field plane of the projection exposure apparatus,
a storage device that stores reference values of an optical parameter over at least one predefined surface,
a data processing apparatus programmed to determine a deviation of predicted values of the optical parameter over the at least one predefined surface from the reference values from the detected intensity distribution.

14. A microlithographic projection exposure apparatus comprising a system as claimed in claim 13.
